(19) United States
(12) Patent Application Publication
(10) Pub. No.: US 2025/0364522 A1
(43) Pub. Date: Nov. 27, 2025

(54) SEMICONDUCTOR PACKAGE AND METHODS OF MANUFACTURING

(71) Applicant: Taiwan Semiconductor Manufacturing Copmpany, Ltd., Hsinchu (TW)

(72) Inventors: Po-Chen LAI, Hsinchu (TW); Ming-Chih YEW, Hsinchu City (TW); Li-Ling LIAO, Hsinchu City (TW); Yu-Sheng LIN, Zhubei (TW); Shin-Puu JENG, Hsinchu (TW)

(21) Appl. No.: 19/294,763

(22) Filed: Aug. 8, 2025

Related U.S. Application Data
(62) Division of application No. 17/805,566, filed on Jun. 6, 2022.

(51) Int. Cl. H01L 25/00; H01L 23/00; H01L 23/538; H01L 25/065; H01L 25/10; H01L 25/16

(52) U.S. Cl. CPC H01L 25/50; H01L 23/5383; H01L 23/5386; H01L 23/5389; H01L 24/16; H01L 24/32; H01L 24/73; H01L 25/0652; H01L 25/105; H01L 25/16; H01L 25/162; H01L 23/5385; H01L 2224/16227; H01L 2224/16238; H01L 2224/32225; H01L 2224/73204; H01L 2225/1041; H01L 2225/107; H01L 2924/1431; H01L 2924/15153; H01L 2924/3511; H01L 2924/37001

(57) ABSTRACT

A semiconductor package, which may correspond to a high-performance computing package, includes an interposer, a substrate, and an integrated circuit device between the interposer and the substrate. The integrated circuit device, which may correspond to an integrated passive device, is attached to the interposer within a cavity of the interposer. Attaching the integrated circuit device within the cavity of the interposer creates a clearance between the integrated circuit device and the substrate. In this way, a likelihood of the integrated circuit device contacting the substrate during a bending and/or a deformation of the semiconductor package is reduced. By reducing the likelihood of such contact, damage to the integrated circuit device and/or the substrate may be avoided to increase a reliability and/or yield of the semiconductor package.

### RELATED APPLICATION

This application is a division of U.S. patent application Ser. No. 17/805,566, filed Jun. 6, 2022, which is incorporated herein by reference in its entirety.

### BACKGROUND

A high-performance computing (HPC) semiconductor package may include one or more integrated circuit (IC) dies, or chips, from a semiconductor wafer, such as a system-on-chip (SoC) IC die, a dynamic random access memory (DRAM) IC die, or a high bandwidth memory (HBM) IC die. The HPC semiconductor package may include an interposer that provides an interface between the one or more IC dies and a substrate. The HPC semiconductor package may further include one or more connection structures to provide electrical connectivity for signaling between the one or more IC dies, the interposer, and the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example implementation of a semiconductor package described herein.

FIGS. 3A, 3B, 4A-4D, 5A, 5B, and 6A-6H are diagrams of example implementations described herein.

FIG. 7 is a diagram of example components of one or more devices of FIG. 1 described herein.

FIGS. 8 and 9 are flowcharts of processes associated with forming a semiconductor package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a semiconductor package, such as an HPC semiconductor package, a plurality of semiconductor dies (or semiconductor chips that include one or more semiconductor dies) may be packaged along with an interposer (e.g., a silicon redistribution layer (RDL) or another type of organic interposer) and bonded to a substrate by controlled collapse chip connection (C4) bumps. An integrated circuit (IC) device, such as an integrated passive device (IPD), may be attached to the interposer and may be positioned between the interposer and the substrate. The IC device may be suspended from the interposer. The IC device may include extra back-end-of-line (BEOL) metal routings, splitters, filters, and/or other passive semiconductor components to increase system performance of the semiconductor package.

In some cases, the semiconductor package may experience stress and/or strain, which can cause the semiconductor package to flex. For example, thermal stress as the operating temperature of the semiconductor package increases may result in bending and/or deformation of the semiconductor package. The bending/deformation can cause the IC device to come into contact with the substrate, which can result in damage to the IC device and/or to the substrate and can cause the semiconductor package to fail.

Some implementations herein describe a semiconductor package. The semiconductor package, which may correspond to a high-performance computing (HPC) package, includes an interposer, a substrate, and an IC device between the interposer and the substrate. The IC device, which may correspond to an IPD, is attached to the interposer within a cavity of the interposer. Attaching the IC device within the cavity of the interposer creates a clearance between the IC device and the substrate.

In this way, a likelihood of the IC device contacting the substrate during a bending and/or a deformation of the semiconductor package is reduced. By reducing the likelihood of such contact, damage to the IC device and/or the substrate may be avoided to increase a reliability and/or yield of the semiconductor package.

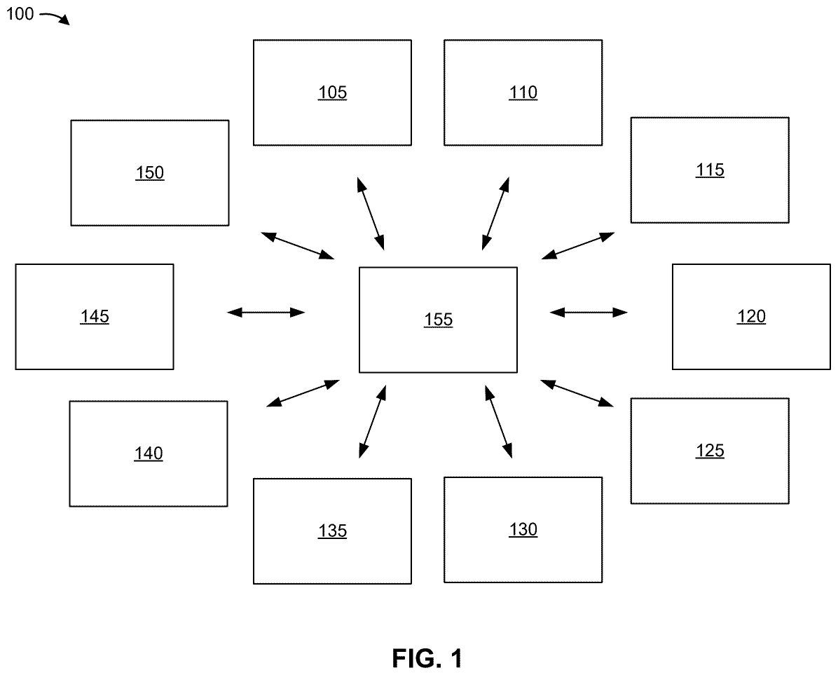

FIG. 1 is a diagram of an example environment 100 in which systems and/or methods described herein may be implemented. As shown in FIG. 1, environment 100 may include a plurality of semiconductor processing tool sets 105-150 and a transport tool set 155. The plurality of semiconductor processing tool sets 105-150 may include a redistribution layer (RDL) tool set 105, a planarization tool set 110, an interconnect tool set 115, an automated test equipment (ATE) tool set 120, a singulation tool set 125, a die-attach tool set 130, an encapsulation tool set 135, a printed circuit board (PCB) tool set 140, a surface mount (SMT) tool set 145, and a finished goods tool set 150. The semiconductor processing tool sets 105-150 of example environment 100 may be included in one or more facilities, such as a semiconductor clean or semi-clean room, a semiconductor foundry, a semiconductor processing facility, an outsourced assembly and test (OSAT) facility, and/or a manufacturing facility, among other examples.

In some implementations, the semiconductor processing tool sets 105-150, and operations performed by the semiconductor processing tool sets 105-150, are distributed across multiple facilities. Additionally, or alternatively, one or more of the semiconductor processing tool sets 105-150 may be subdivided across the multiple facilities. Sequences of operations performed by the semiconductor processing tool sets 105-150 may vary based on a type of the semiconductor package or a state of completion of the semiconductor package.

One or more of the semiconductor processing tool sets 105-150 may perform a series of operations to assemble a semiconductor package (e.g., attach one or more IC dies to a substrate, where the substrate provides an external connectivity to a computing device, among other examples). Additionally, or alternatively, one or more of the semiconductor processing tool sets 105-150 may perform a series of operations to ensure a quality and/or a reliability of the semiconductor package (e.g., test and sort the one or more IC dies, and/or the semiconductor package, at various stages of manufacturing).

The semiconductor package may correspond to a type of semiconductor package. For example, the semiconductor package may correspond to a flipchip (FC) type of semiconductor package, a ball grid array (BGA) type of semiconductor package, a multi-chip package (MCP) type of semiconductor package, or a chip scale package (CSP) type of semiconductor package. Additionally, or alternatively, the semiconductor package may correspond to a plastic leadless chip carrier (PLCC) type of semiconductor package, a system-in-package (SIP) type of semiconductor package, a ceramic leadless chip carrier (CLCC) type of semiconductor package, or a thin small outline package (TSOP) type of semiconductor package, among other examples.

The RDL tool set 105 includes one or more tools capable of forming one or more layers and patterns of materials (e.g., dielectric layers, conductive redistribution layers, and/or vertical interconnect access structures (vias), among other examples) on a semiconductor substrate (e.g., a semiconductor wafer, among other examples). The RDL tool set 105 may include a combination of one or more photolithography tools (e.g., a photolithography exposure tool, a photoresist dispense tool, a photoresist develop tool, among other examples), a combination of one or more etch tools (e.g., a plasma-based etched tool, a dry-etch tool, or a wet-etch tool, among other examples), and one or more deposition tools (e.g., a chemical vapor deposition (CVD) tool, a physical vapor deposition (PVD) tool, an atomic layer deposition (ALD) tool, or a plating tool, among other examples). The RDL tool set 105 may further include a bonding/debonding tool for joining, and/or separating, semiconductor substrates (e.g., semiconductor wafers). In some implementations, the example environment 100 includes a plurality of types of such tools as part of RDL tool set 105.

The planarization tool set 110 includes one or more tools that are capable of polishing or planarizing various layers of the semiconductor substrate (e.g., the semiconductor wafer). The planarization tool set 110 may also include tools capable of thinning the semiconductor substrate. The planarization tool set 110 may include a chemical mechanical planarization (CMP) tool or a lapping tool, among other examples. In some implementations, the example environment 100 includes a plurality of types of such tools as part of the planarization tool set 110.

The interconnect tool set 115 includes one or more tools that are capable of forming connection structures (e.g., electrically-conductive structures) as part of the semiconductor package. The connection structures formed by the interconnect tool set 115 may include a wire, a stud, a pillar, a bump, or a solderball, among other examples. The connection structures formed by the interconnect tool set 115 may include materials such as a gold (Au) material, a copper (Cu) material, a silver (Ag) material, a nickel (Ni) material, a tin (Sn) material, or a palladium (Pd) material, among other examples. The interconnect tool set 115 may include a bumping tool, a wirebond tool, or a plating tool, among other examples. In some implementations, the example environment 100 includes a plurality of types of such tools as part of the interconnect tool set 115.

The ATE tool set 120 includes one or more tools that are capable of testing a quality and a reliability of the one or more IC dies and/or the semiconductor package (e.g., the one or more IC dies after encapsulation). The ATE tool set 120 may perform wafer testing operations, known good die (KGD) testing operations, semiconductor package testing operations, or system-level (e.g., a circuit board populated with one or more semiconductor packages and/or one or more IC dies) testing operations, among other examples. The ATE tool set 120 may include a parametric tester tool, a speed tester tool, and/or a burn-in tool, among other examples. Additionally, or alternatively, the ATE tool set 120 may include a prober tool, probe card tooling, test interface tooling, test socket tooling, a test handler tool, burn-in board tooling, and/or a burn-in board loader/unloader tool, among other examples. In some implementations, the example environment 100 includes a plurality of types of such tools as part of the ATE tool set 120.

The singulation tool set 125 includes one or more tools that are capable of singulating (e.g., separating, removing) the one or more IC dies or the semiconductor package from a carrier. For example, the singulation tool set 125 may include a dicing tool, a sawing tool, or a laser tool that cuts the one or more IC dies from the semiconductor substrate. Additionally, or alternatively, the singulation tool set 125 may include a trim-and-form tool that excises the semiconductor package from a leadframe. Additionally, or alternatively, the singulation tool set 125 may include a router tool or a laser tool that removes the semiconductor package from a strip or a panel of an organic substrate material, among other examples. In some implementations, the example environment 100 includes a plurality of types of such tools as part of the singulation tool set 125.

The die-attach tool set 130 includes one or more tools that are capable of attaching the one or more IC dies to the interposer, the leadframe, and/or the strip of the organic substrate material, among other examples. The die-attach tool set 130 may include a pick-and-place tool, a taping tool, a laminating tool, a reflow tool (e.g., a furnace), a soldering tool, or an epoxy dispense tool, among other examples. In some implementations, the example environment 100 includes a plurality of types of such tools as part of the die-attach tool set 130.

The encapsulation tool set 135 includes one or more tools that are capable of encapsulating the one or more IC dies (e.g., the one or more IC dies attached to the interposer, the leadframe, or the strip of organic substrate material). For example, the encapsulation tool set 135 may include a molding tool that encapsulates the one or more IC dies in a plastic molding compound. Additionally, or alternatively, the encapsulation tool set 135 may include a dispense tool that dispenses an epoxy polymer underfill material between the one or more IC dies and an underlying surface (e.g., the interposer or the strip of organic substrate material, among other examples). In some implementations, the example environment 100 includes a plurality of types of such tools as part of the encapsulation tool set 135.

The PCB tool set 140 incudes one or more tools that are capable of forming a PCB having one or more layers of electrically-conductive traces. The PCB tool set 140 may form a type of PCB, such as a single layer PCB, a multi-layer PCB, or a high density interconnect (HDI) PCB, among other examples. In some implementations, the PCB tool set 140 forms the interposer and/or the substrate. The PCB tool set 140 may include a laminating tool, a plating tool, a photoengraving tool, a laser cutting tool, a pick-and-place tool, an etching tool, a dispense tool, and/or a curing tool (e.g., a furnace) among other examples. In some implementations, the example environment 100 includes a plurality of types of such tools as part of the PCB tool set 140.

The SMT tool set 145 includes one or more tools that are capable of mounting the semiconductor package to a circuit board (e.g., a central processing unit (CPU) PCB, a memory module PCB, an automotive circuit board, and/or a display system board, among other examples). The SMT tool set 145 may include a stencil tool, a solder paste printing tool, a pick-and-place tool, a reflow tool (e.g., a furnace), and/or an inspection tool, among other examples. In some implementations, the example environment 100 includes a plurality of types of such tools as part of the SMT tool set 145.

The finished goods tool set 150 includes one or more tools that are capable of preparing a final product including the semiconductor package for shipment to a customer. The finished goods tool set 150 may include a tape-and-reel tool, a pick-and-place tool, a carrier tray stacking tool, a boxing tool, a drop-testing tool, a carousel tool, a controlled-environment storage tool, and/or a sealing tool, among other examples. In some implementations, the example environment 100 includes a plurality of types of such tools as part of the finished goods tool set 150.

The transport tool set 155 includes one or more tools that are capable of transporting work-in-process (WIP) between the semiconductor processing tool sets 105-150. The transport tool set 155 may be configured to accommodate one or smore transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples). The transport tool set 155 may also be configured to transfer and/or combine WIP amongst transport carriers. The transport tool set 155 may include a pick-and-place tool, a conveyor tool, a robot arm tool, an overhead hoist transport (OHT) tool, an automated materially handling system (AMHS) tool, and/or another type of tool. In some implementations, the example environment 100 includes a plurality of types of such tools as part of the transport tool set 155.

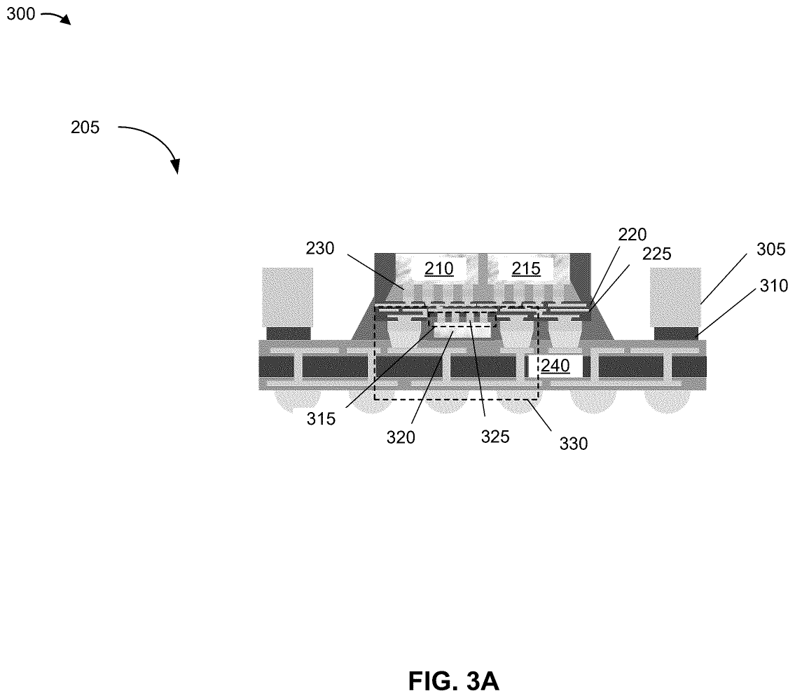

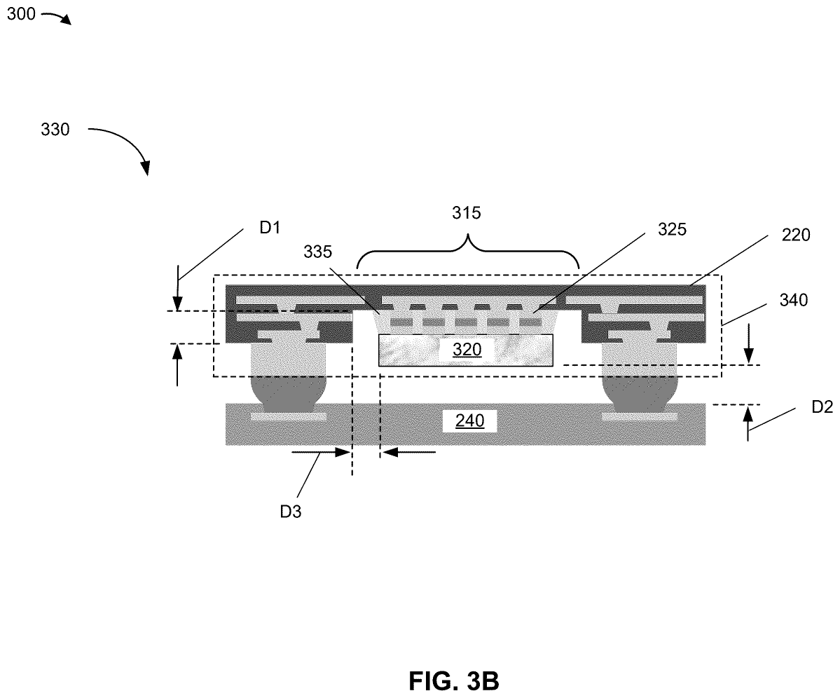

One or more of the semiconductor processing tool sets 105-150 may perform a series of operations. For example, and as described in greater detail in connection with FIGS. 3A-9 and elsewhere herein, the series of operations includes forming a cavity within a first surface of an interposer having interspersed layers of electrically-conductive traces. The series of operations also includes attaching an IC device to the interposer within the cavity. The series of operations also includes attaching a substrate to a second surface of the interposer that is opposite the first surface.

Additionally, or alternatively, the series of operations includes joining a top surface of a first temporary carrier and a bottom surface of an interposer having interspersed layers of electrically-conductive traces. The series of operations includes attaching a first IC device to a top surface of the interposer. The series of operations includes joining a top surface of the first IC device and a surface of a second temporary carrier. The series of operations includes separating the bottom surface of the interposer from the top surface of the first temporary carrier. The method includes forming a cavity in the bottom surface of the interposer. The method includes attaching, within the cavity, an IPD to a layer of the interspersed layers of electrically-conductive traces.

The number and arrangement of tool sets shown in FIG. 1 are provided as one or more examples. In practice, there may be additional tool sets, different tool sets, or differently arranged tool sets than those shown in FIG. 1. Furthermore, two or more tool sets shown in FIG. 1 may be implemented within a single tool set, or a tool set shown in FIG. 1 may be implemented as multiple, distributed tool sets. Additionally, or alternatively, one or more tool sets of environment 100 may perform one or more functions described as being performed by another tool set of environment 100.

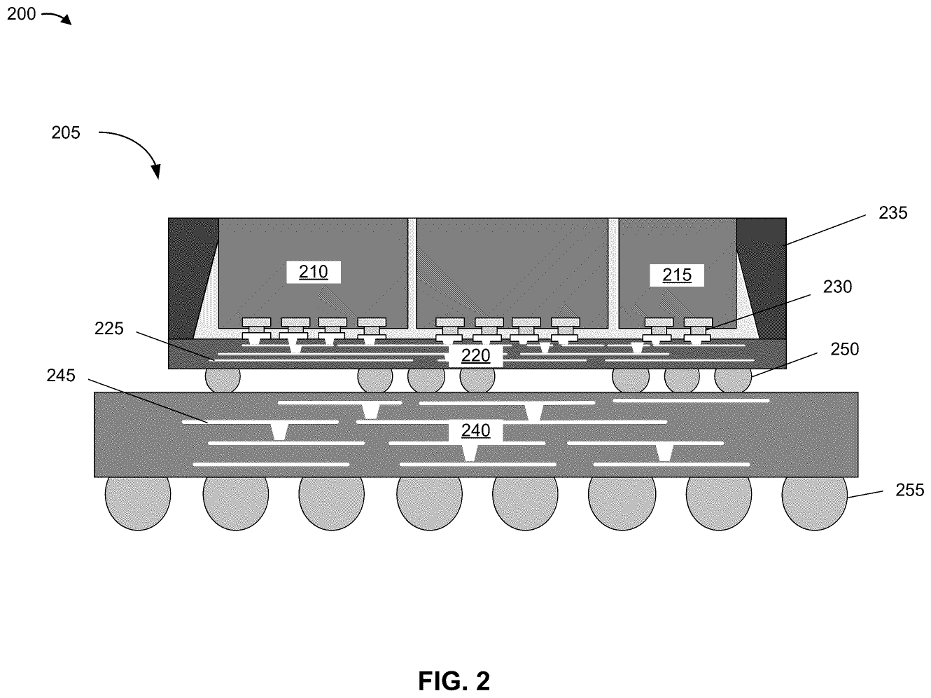

FIG. 2 is a diagram of an example implementation 200 of a semiconductor package 205 described herein. In some implementations, the semiconductor package 205 corresponds to a high-performance computing (HPC) semiconductor package. Furthermore, FIG. 2 represents a side view of the of the semiconductor package 205.

The semiconductor package 205 may include one or more IC dies (e.g., a system-on-chip (SoC) IC die 210 and/or a dynamic random access memory (DRAM) IC die 215, among other examples). The semiconductor package 205 may include an interposer 220 having one or more layers of electrically-conductive traces 225. The interposer 220 may include one or more layers of a dielectric material, such as a ceramic material or a silicon material. In some implementations, the interposer 220 corresponds to a PCB including layers of a glass-reinforced epoxy laminate material and/or a pre-preg material (e.g., a composite fiber/resin/epoxy material), among other examples. Additionally, or alternatively, one or more layers of the interposer 220 may include a buildup film material.

The electrically-conductive traces 225 may include one or more materials such as a gold (Au) material, a copper (Cu) material, a silver (Ag) material, a nickel (Ni) material, a tin (Sn) material, or a palladium (Pd) material, among other examples. In some implementations, the interposer 220 includes one or more conductive vertical interconnect access structures (vias) that connect one or more layers of the electrically-conductive traces 225.

As shown in FIG. 2, the SoC IC die 210 and the DRAM IC die 215 are connected (e.g., mounted) to the interposer 220 using a plurality of connection structures 230. The connection structures 230 may include one or more combinations of a stud, a pillar, a bump, or a solderball, among other examples. The connection structures 230 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 230 may connect lands (e.g., pads) on bottom surfaces of the SoC IC die 210 and the DRAM IC die 215 to lands on a top surface of the interposer 220. In some implementations, the connection structures 230 may include one or more electrical connections for signaling (e.g., corresponding lands of the SoC IC die 210, the DRAM IC die 215, and the interposer 220 are electrically connected to respective circuitry and/or traces of the SoC IC die 210, the DRAM IC die 215, and the interposer 220).

In some implementations, the connection structures 230 may include one or more mechanical connections for attachment purposes and/or spacing purposes (e.g., corresponding lands of the SoC IC die 210, the DRAM IC die 215, and the interposer 220 are not electrically connected to respective circuitry and/or traces of the SoC IC die 210, the DRAM IC die 215, and the interposer 220). In some implementations, one or more of the connection structures 230 may function both electrically and mechanically.

A mold compound 235 may encapsulate one or more portions of the semiconductor package 205, including portions of the SoC IC die 210 and/or the DRAM IC die 215. The mold compound 235 (e.g., a plastic mold compound, among other examples) may protect the SoC IC die 210 and/or the DRAM IC die 215 from damage during manufacturing of the semiconductor package 205 and/or during field use of the semiconductor package 205.

The semiconductor package 205 may include a substrate 240 having one or more layers of electrically-conductive traces 245. The substrate 240 may include one or more layers of a dielectric material, such as a ceramic material or a silicon material. In some implementations, the substrate 240 corresponds to a PCB including layers of a glass-reinforced epoxy laminate material and/or a pre-preg material (e.g., a composite fiber/resin/epoxy material), among other examples. Additionally, or alternatively, one or more layers of the substrate 240 may include a buildup film material.

The electrically-conductive traces 245 may include one or more materials such as a gold (Au) material, a copper (Cu) material, a silver (Ag) material, a nickel (Ni) material, a tin (Sn) material, or a palladium (Pd) material, among other examples. In some implementations, the substrate 240 includes one or more conductive vertical interconnect access structures (vias) that connect one or more layers of the electrically-conductive traces 245.

As shown in FIG. 2, the interposer 220 is connected (e.g., mounted) to the substrate 240 using a plurality of connection structures 250. The connection structures 250 may include one or more combinations of a stud, a pillar, a bump, or a solderball, among other examples. In some implementations, the connection structures 250 correspond to controlled collapse chip connection (C4) connection structures. The connection structures 250 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 250 may connect lands (e.g., pads) on a bottom surface of the interposer 220 to lands on a top surface of the substrate 240. In some implementations, the connection structures 250 may include one or more electrical connections for signaling (e.g., corresponding lands of the interposer 220 and the substrate 240 are electrically connected to respective circuitry and/or traces of the interposer 220 and the substrate 240). In some implementations, the connection structures 250 may include or more mechanical connections for attachment purposes and/or spacing purposes (e.g., corresponding lands of the interposer 220 and the substrate 240 are not electrically connected to respective circuitry and/or traces of the interposer 220 and the substrate 240). In some implementations, one or more of the connection structures 250 may function both electrically and mechanically.

The semiconductor package 205 may include a plurality of connection structures 255 connected to lands (e.g., pads) on a bottom surface of the substrate 240. The connection structures 255 may include one or more combinations of a stud, a pillar, a bump, or a solderball, among other examples. The connection structures 255 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free). In some implementations, the connection structures 255 correspond to C4 connection structures.

The connection structures 255 may be used to attach the semiconductor package 205 (e.g., the substrate 240) to a circuit board (not shown) using a surface mount (SMT) process. In some implementations, the connection structures 255 may provide an electrical connection for signaling (e.g., corresponding lands of the substrate 240 and the circuit board may be electrically connected to respective circuitry and/or traces of the substrate 240 and the circuit board). In some implementations, the connection structures 250 may provide a mechanical connection to the circuit board for attachment purposes and/or spacing purposes (e.g., corresponding lands of the substrate 240 and the circuit board may not be electrically connected to respective circuitry and/or traces of the substrate 240 and the circuit board). In some implementations, one or more of the connection structures 250 may provide both mechanical and electrical connections.

As described in greater detail in connection with FIGS. 3A and 3B, and elsewhere herein, the semiconductor package 205 includes an interposer (e.g., the interposer 220) having interspersed layers of electrically-conductive traces (e.g., the electrically-conductive traces 225) and a bottom surface having a cavity, where the cavity has a recessed surface. The semiconductor package 205 includes a substrate (e.g., the substrate 240) below the interposer including a top surface, where the top surface is electrically and/or mechanically connected to the bottom surface of the interposer using a first set of connection structures (e.g., the connection structures 255). The semiconductor package 205 includes an IC device between the interposer and the substrate, where a top surface of the IC device is electrically and/or mechanically connected within the cavity using a second set of connection structures, and where the IC device is electrically connected to the interspersed layers of electrically-conductive traces using the second set of connection structures.

As indicated above, FIG. 2 is provided as an example. Other examples may differ from what is described with regard to FIG. 2.

FIGS. 3A and 3B are diagrams of an example implementation 300 described herein. Example implementation 300 may include the semiconductor package 205 formed using a combination of operations performed by one or more of the semiconductor processing tools 105-150 as described in connection with FIG. 1. Furthermore, FIGS. 3A and 3B represent side views the semiconductor package 205.

As shown in FIG. 3A, the semiconductor package 205 includes the SoC IC die 210, the DRAM IC die 215, the interposer 220, and the substrate 240 as described in connection with FIG. 2. The SoC IC die 210 and the DRAM IC die 215 are mounted to a top surface of the interposer 220 (e.g., mounted to lands or traces at a top surface of the interposer 220 using the connection structures 230). Within the interposer 220 of FIG. 3A, the electrically-conductive traces 225 may correspond to interspersed layers of electrically-conductive traces (e.g., layers of electrically-conductive traces alternating with dielectric layers in a vertical direction and formed using a redistribution layer process or a multi-layer printed circuit board process, among other examples).

The semiconductor package 205 may, as shown in FIG. 3A, include a stiffener structure 305 (e.g., a stiffener ring formed from plastic, among other examples) attached to the substrate 240 using an adhesive 310. The stiffener structure 305 may prevent a warpage and/or a bowing of the semiconductor package 205.

Further, as shown in FIG. 3A, a bottom surface of the interposer 220 includes a cavity 315. The cavity 315 includes a recessed surface, to which an IC device 320 is mounted using connection structures 325 (e.g., a set of one or more structures that electrically and/or mechanically connect IC device 320 to lands at the recessed surface of the cavity 315 or to the electrically-conductive traces 225 at or below the recessed surface of the cavity 315). The IC device 320 may correspond to an integrated passive device (IPD) such as a capacitor, among other examples. Additionally, or alternatively, the IC device 320 may correspond to a bare IC die or a packaged (e.g., encapsulated) IC die.

The connection structures 325 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free). In some implementations, one or more of the connection structures 325 include one or more underbump metallization (UBM) structures (e.g., layers). The UBM structures may include a combination of a nickel (Ni) material, a copper (Cu) material, and/or a copper (Cu)/Nickel (Ni)/Tin (Sn) intermetallic compound, among other examples. Additionally, or alternatively, one or more of the connection structures 325 may include one or more solder plating structures (e.g., layers). The solder plating structures may include a combination of a tin-copper (SnCu) material, a tin-nickel material (SnNi), or a tin-copper-nickel germanium (SnCuNiGe) material, among other examples.

In contrast to a semiconductor package in which the IC device 320 may be mounted to via structures of an interposer, the semiconductor package 205 of FIG. 3A including the IC device 320 mounted to the electrically-conductive traces 225 (e.g., mounted to at least one layer of interspersed layers of electrically-conductive traces) may be relatively thinner. Additionally, or alternatively, the electrically-conductive traces 225 may be routable to accommodate differing pin outs (e.g., pad or signaling configurations, among other examples) between the IC device 320, the SoC IC die 210, and/or the DRAM IC die 215.

As described in connection with FIG. 3B, a region 330 of the semiconductor package 205 includes the cavity 315 (e.g., a surface that is recessed from the bottom surface of the interposer 220). One or more dimensional properties of the cavity 315 within the region 330 may create a clearance between the IC device 320 and the substrate 240. In this way, a likelihood of the IC device 320 contacting the substrate 240 during a bending and/or deformation of the semiconductor package 205 is reduced. By reducing the likelihood of such contact, damage to the IC device 320 and/or the substrate 240 may be avoided to increase a reliability and/or yield of the semiconductor package 205.

FIG. 3B show additional details of the region 330 of the semiconductor package 205. FIG. 3B, a side-view of the semiconductor package 205, includes the interposer 220 over the substrate 240. As shown in FIG. 3B, the IC device 320 is mounted within the cavity 315 (e.g. to the bottom surface of the cavity 315) using the connection structures 325.

In some implementations, and as shown in FIG. 3B, an underfill material 335 may be between the recessed surface of the cavity 315 and the IC device 320. The underfill material 335 may surround the connection structures 325 to improve a robustness of the mechanical and/or electrical connections between the IC device 320 and the recess of the cavity 315. The underfill material 335 may include an epoxy polymer material, among other examples.

As shown in FIG. 3B, the cavity 315 includes a depth D1 which may correspond to a length of an approximately vertical wall of the cavity 315. As an example, the depth D1 (e.g., the length of the approximately vertical wall of the cavity 315) may be greater than approximately 15 microns. If the depth D1 is equal to or less than approximately 15 microns, a tolerance stack and/or a flexure within the semiconductor package 205 may cause a bottom surface of the IC device 320 to collide or interfere with the top surface of the substrate 240. However, other values and ranges for the depth D1 are within the scope of the present disclosure.

The depth D1 may combine with a thickness of the IC device 320 and/or a length of the connection structures 325 to provide a clearance D2 between a bottom surface of IC device 320 and a top surface of the substrate 240. As an example, the clearance D2 may be included in a range of approximately 10 microns to approximately 60 microns. If the clearance D2 is less approximately 10 microns, the bottom surface of the IC device 320 may interfere with the top surface of the substrate 240. If the clearance D2 is greater than approximately 60 microns, an overall thickness of the semiconductor package 205 may be increased and consume an inordinate amount of space in a computing system in which the semiconductor package 205 is implemented. However, other values and ranges for the clearance D2 are within the scope of the present disclosure.

As further shown in FIG. 3B, the cavity 315 is configured to provide a clearance D3 between an edge of the IC device 320 and the approximately vertical wall of the cavity 315. As an example, the clearance D3 may be included in a range of approximately 100 microns to approximately 300 microns. If the clearance D3 is less than approximately 100 microns, the edge of the IC device 320 may collide with the approximately vertical wall. If the clearance D3 is greater than approximately 300 microns, a size of the interposer 220 and/or the substrate 240 may increase to add to a cost of the semiconductor package 205. However, other values and ranges for the clearance D3 are within the scope of the present disclosure.

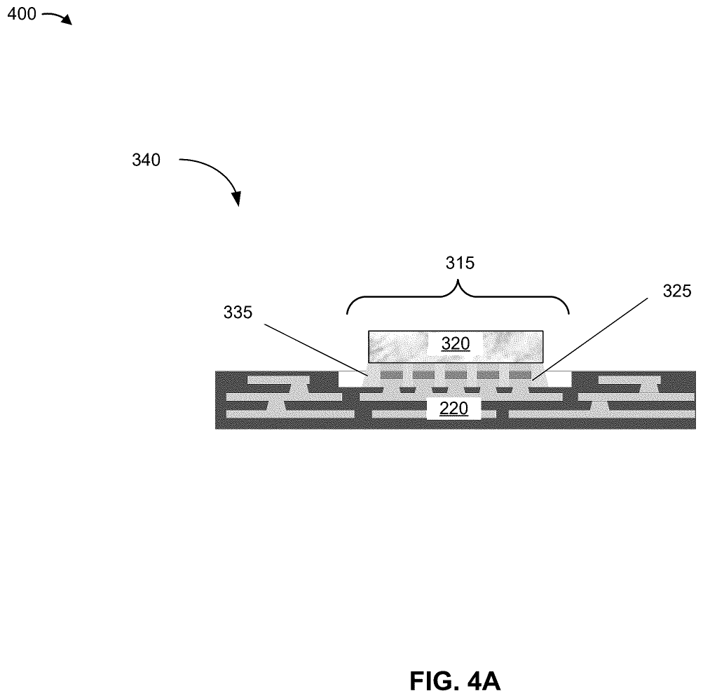

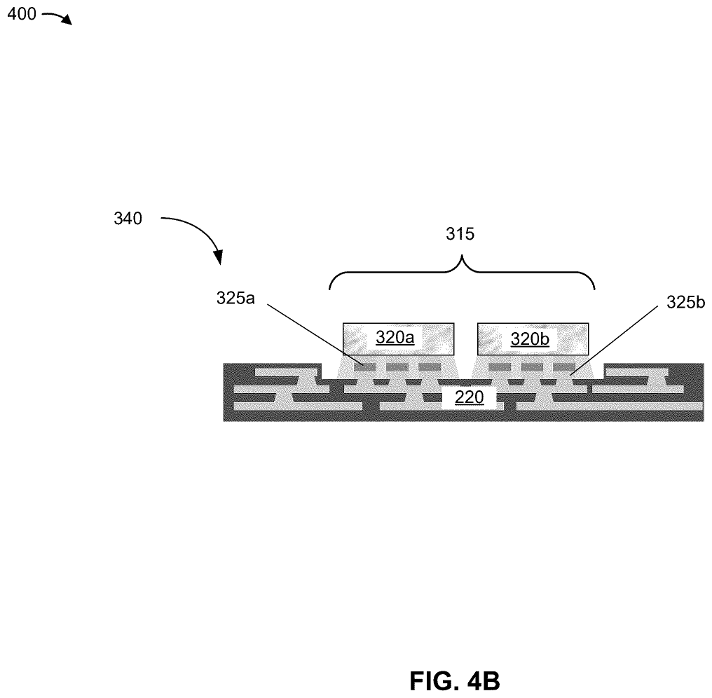

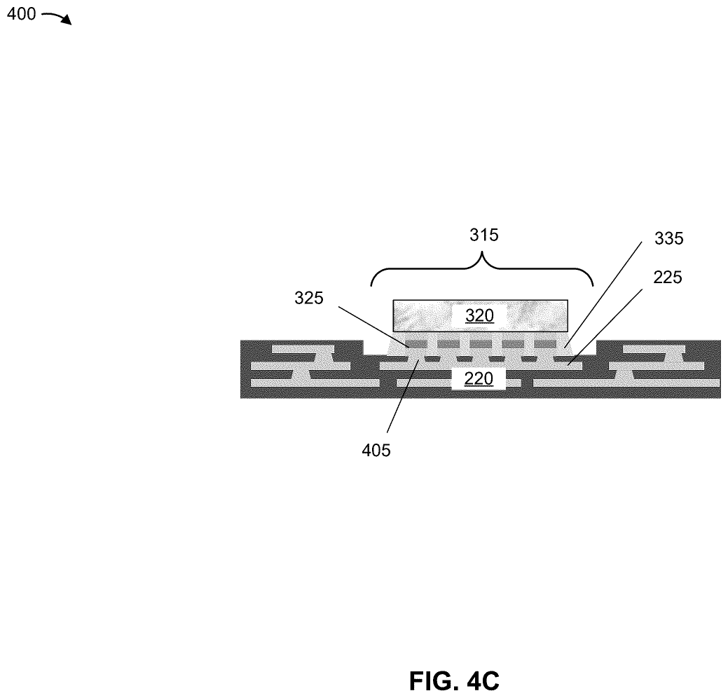

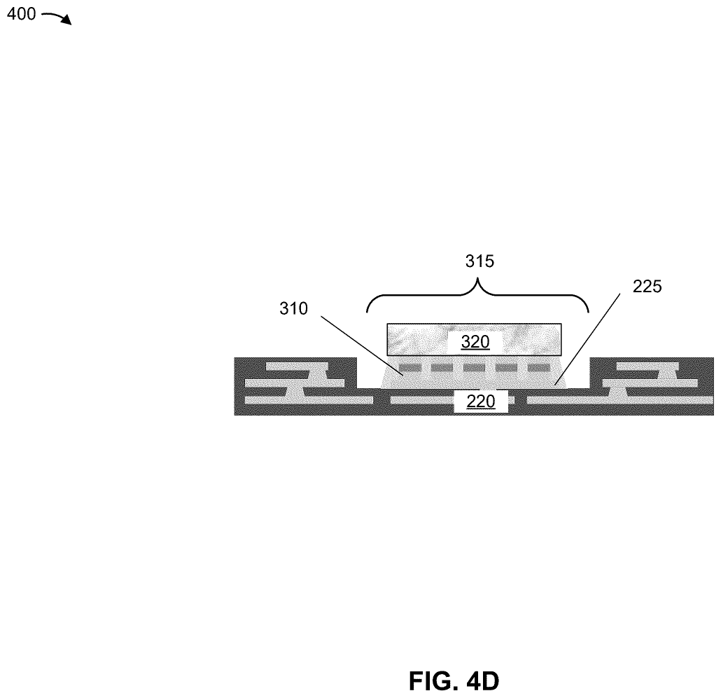

As indicated above, FIGS. 3A and 3B are provided as examples. Furthermore, and described in connection with FIGS. 4A-4D and elsewhere herein, a region 340 of the interposer 220 including the cavity 315 may include additional features, different features, or differently arranged features than those shown in FIGS. 3A and 3B.

FIGS. 4A-4D are diagrams of an example implementation 400 described herein. The implementation 400 includes one or more example configurations of the region 340 including the cavity 315. Additionally, FIGS. 4A-4D represent side views of the region 340.

FIG. 4A shows an example configuration including the IC device 320 (e.g., a single IC device) attached (e.g., mounted) to the interposer 220 (e.g., the bottom surface of the cavity 315). The connection structures 325 are used to attach the IC device 320 to the interposer 220. The underfill material 335 surrounds the connection structures 325.

FIG. 4B shows an example configuration including the IC device 320a and the IC device 320b (e.g., multiple IC devices) attached (e.g., mounted) to the interposer 220 (e.g., the bottom surface of the cavity 315). In FIG. 4B, the IC device 320a and the IC device 320b are disposed side by side (e.g., adjacent to one another). The connection structures 325a are used to attach the IC device 320a to the interposer 220. The connection structures 325b are used to attach the IC device 320b to the interposer 220. The underfill material 335 surrounds the connection structures 325a and 325b.

FIG. 4C shows an example configuration including the IC device 320 attached (e.g., mounted) to the interposer 220 (e.g., the bottom surface of the cavity 315). The connection structures 325 are used to mount the IC device 320 to the interposer 220. In the example configuration of FIG. 4C, the electrically-conductive traces 225 (e.g., at least one layer of the interspersed layers of electrically-conductive traces) are embedded below the bottom surface of the cavity 315. As part of the example configuration of FIG. 4C, the connection structures 325 attach the IC device 320 to land structures 405 that extend through the bottom surface of the cavity 315 (e.g., the connection structures 325 are between the IC device 320 and the land structures 405 exposed at the bottom surface of the cavity 315). The underfill material 335 surrounds the connection structures 325.

FIG. 4D shows an example configuration including the IC device 320 attached (e.g., mounted) to the interposer 220 (e.g., the bottom surface of the cavity 315). The connection structures 325 are used to mount the IC device 320 to the interposer 220. In the example configuration of FIG. 4D, the electrically-conductive traces 225 (e.g., at least one layer of interspersed layers of electrically-conductive traces) are exposed at the bottom surface of the cavity 315. As part of the example configuration of FIG. 4D, the connection structures 325 attach the IC device 320 to the electrically-conductive traces 225 (e.g., the connection structures 325 are between the IC device 320 and the electrically-conductive traces 225 exposed at the bottom surface of cavity 315). The underfill material 335 surrounds the connection structures 325.

As indicated above, FIGS. 4A-4D are provided as examples. Other examples may differ from what is described with regard to FIGS. 4A-4D.

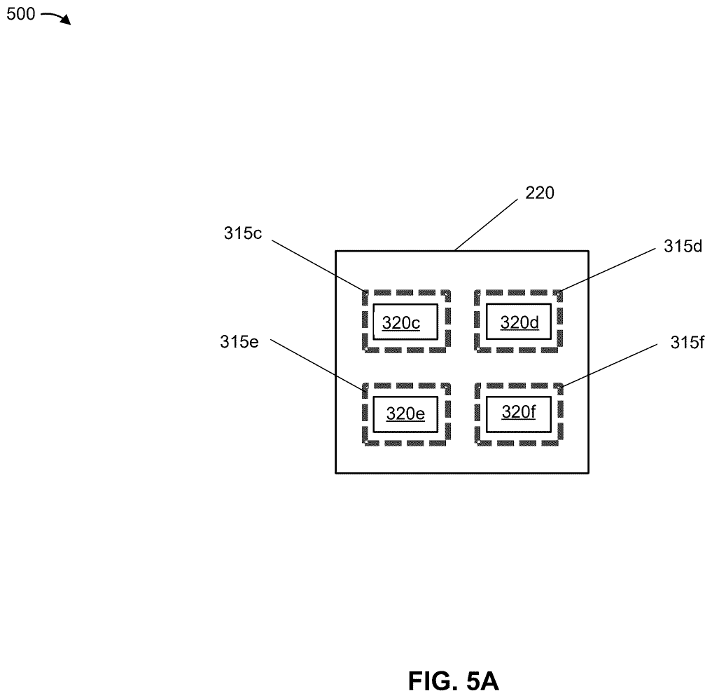

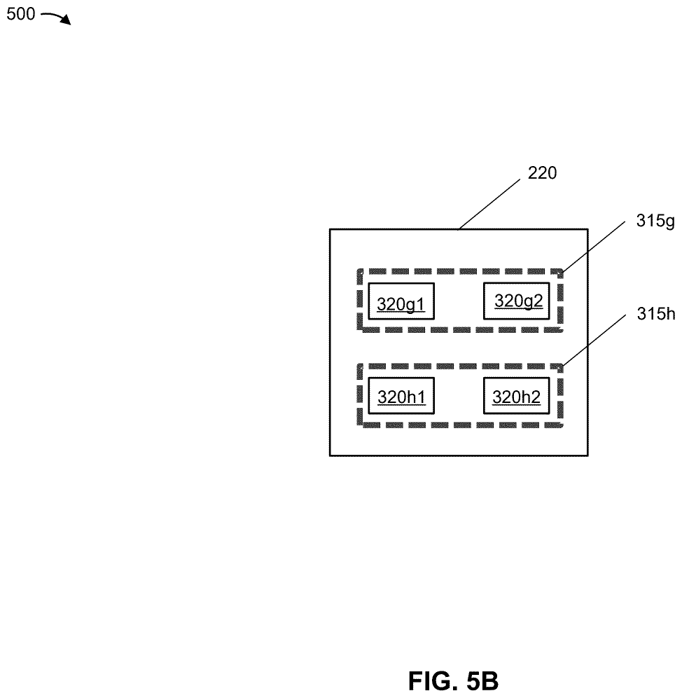

FIGS. 5A and 5B are diagrams of an example implementation 500 described herein. The implementation 500 includes one or more example layouts of the interposer 220, including one or more instances of the cavity 315. Additionally, FIGS. 5A and 5B include top views of the interposer 220.

The example layout shown in FIG. 5A includes the cavities 315c-315f (e.g., rectangular cavities) and the IC devices 320c-320f. As shown in the example layout of FIG. 5A, each cavity includes a single (e.g., an individual) IC device. The example layout of FIG. 5A may provide advantages in a design of a semiconductor package (e.g., the semiconductor package 205) having multiple IC dies (e.g., multiples of the SoC IC die 210 and/or the DRAM IC die 215, among other examples) that are each designed to be paired with a capacitor or IPD (e.g., the IC device 320). The example layout of FIG. 5A may also reduce parasitics of the semiconductor package as a result of short trace lengths between each IC die and the capacitor or IPD with which each IC die is paired.

The example layout shown in FIG. 5B includes the cavities 315g and 315h (e.g., rectangular cavities). As shown, the cavity 315g includes the IC devices 320g1 and 320g2 in a side-by-side (e.g., adjacent) configuration. Further, the cavity 315h includes the IC devices 320h1 and 320h2 in a side-by-side (e.g., adjacent) configuration. The example layout of FIG. 5B may provide advantages in a design of a semiconductor package (e.g., the semiconductor package 205) having one or more IC dies (e.g., one or more of the SoC IC die 210 and/or the DRAM IC die 215, among other examples) that are each designed to be part of an electrical circuit including one or more capacitors or IPDs (e.g., one or more instances of the IC device 320) that are arranged electrically in parallel or in series.

As indicated above, FIGS. 5A and 5B are provided as examples. Other examples may differ from what is described with regard to FIGS. 5A and 5B, including different layouts, quantities of the IC device 320 within the cavity 315, and/or shapes of the cavity 315.

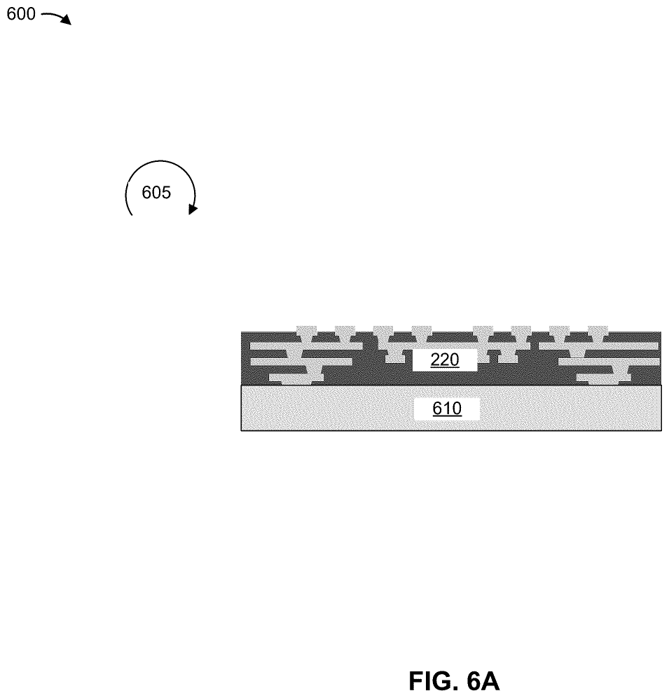

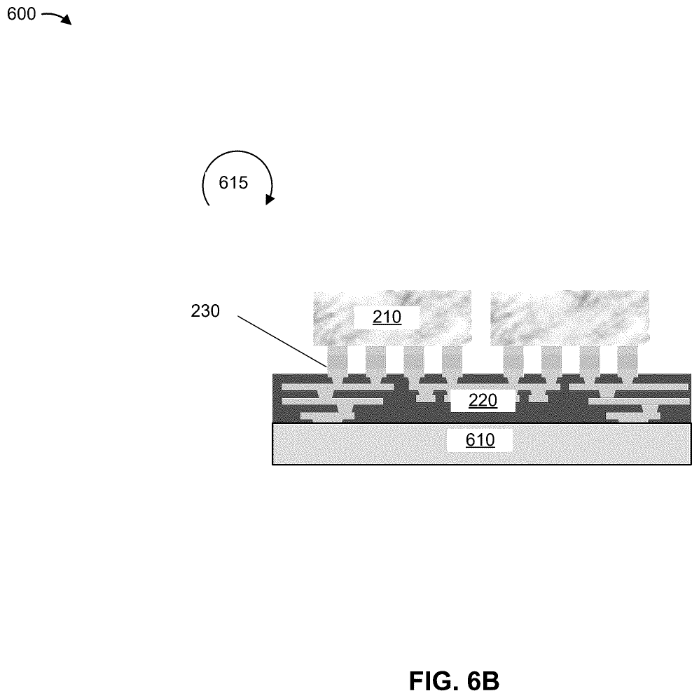

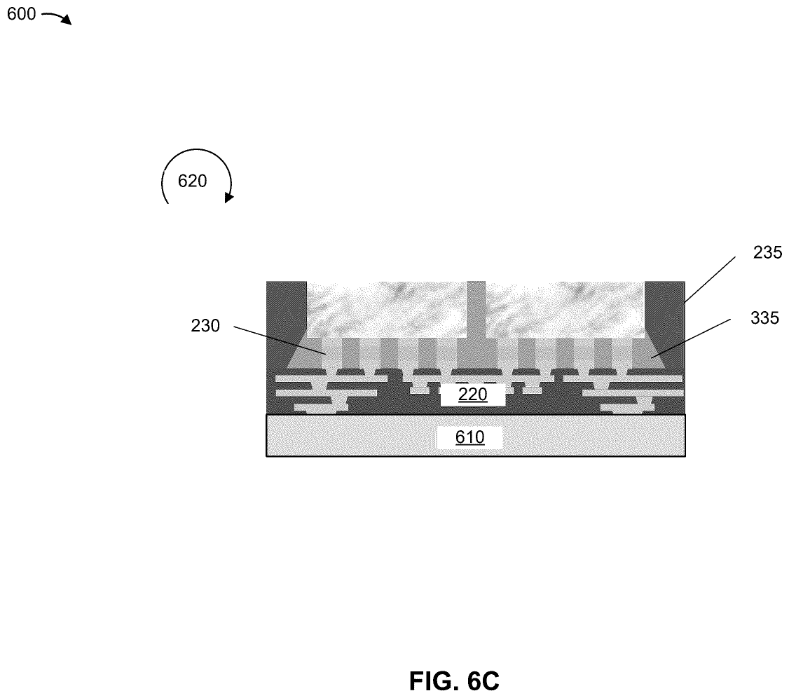

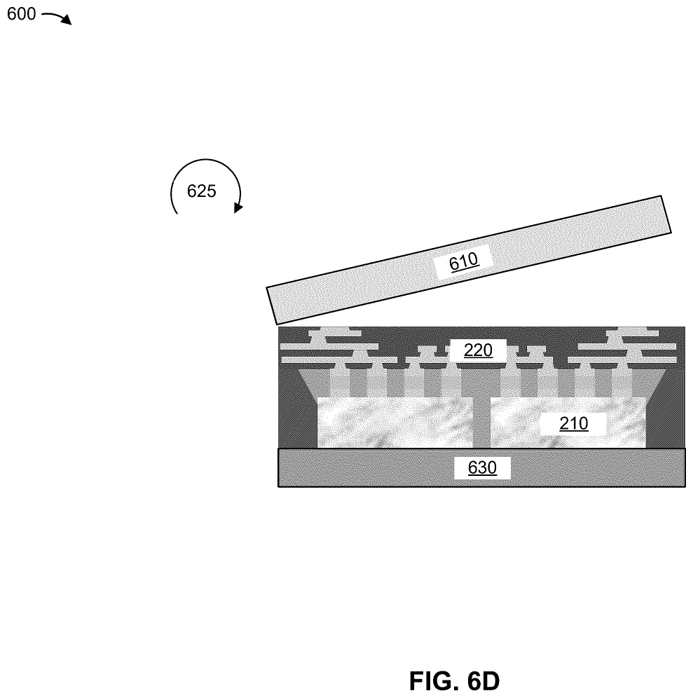

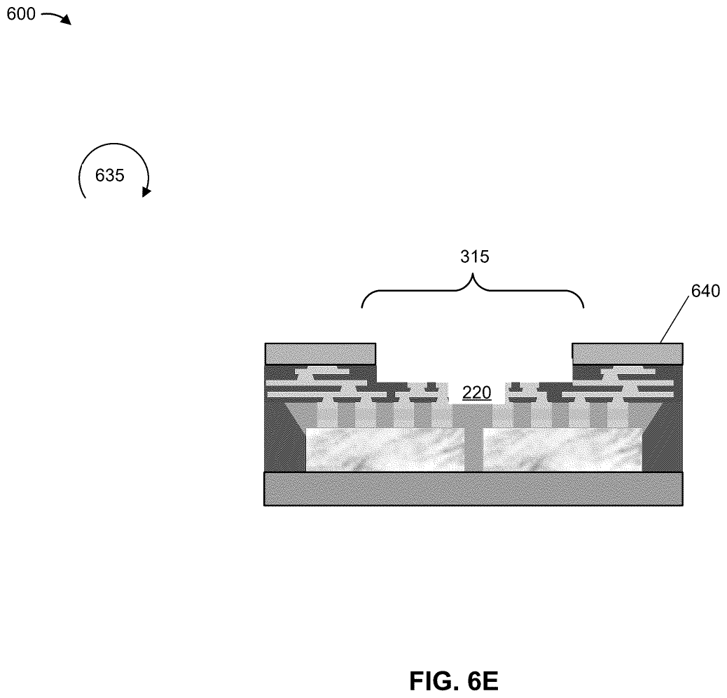

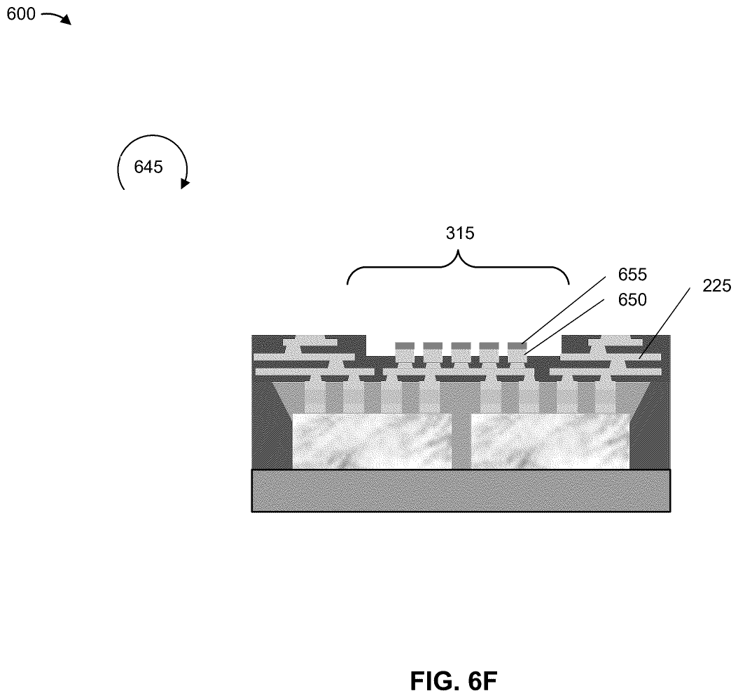

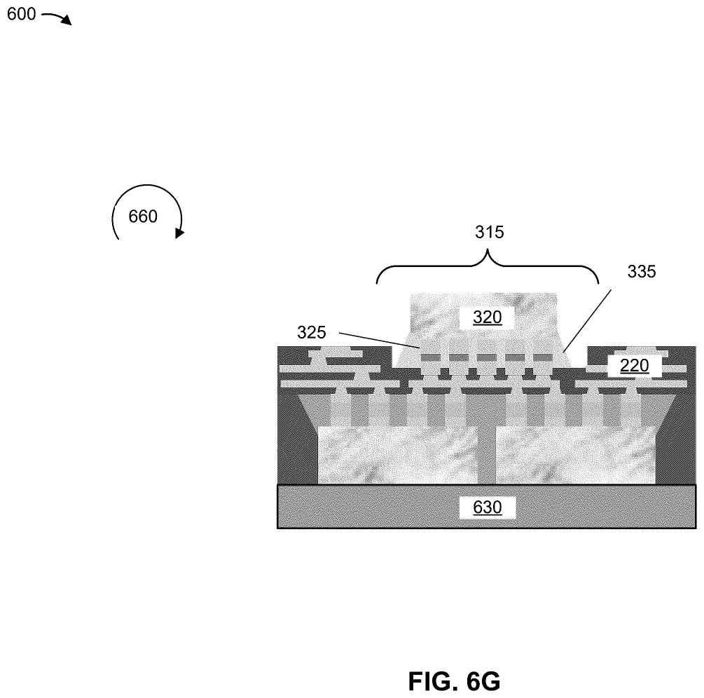

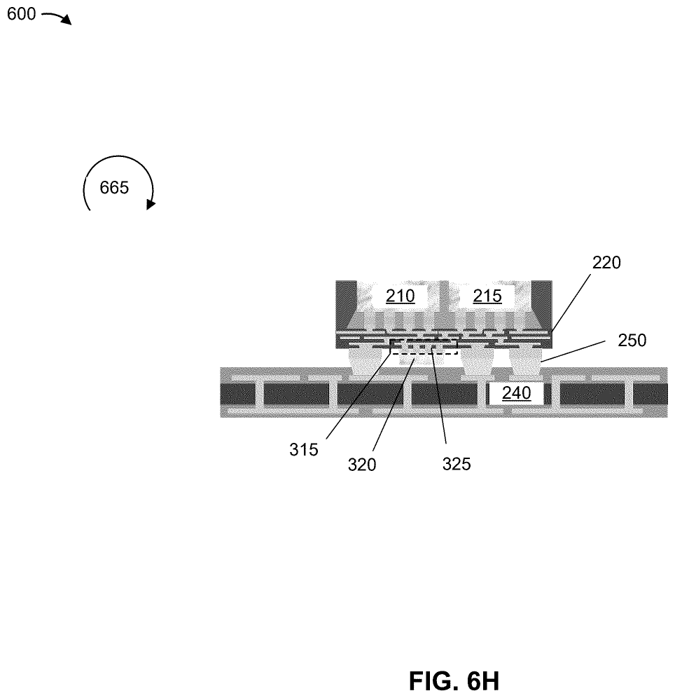

FIGS. 6A-6H are diagrams of an example implementation 600 described herein. The implementation 600 includes a series of operations that may be performed by one or more of the semiconductor processing tool sets 105-150 to form the semiconductor package 205 including cavity 315. In some implementations, the series of operations corresponds to a chip-on-wafer-on-substrate (CoWoS) packaging process.

As shown in FIG. 6A, a semiconductor processing tool set (e.g., the RDL tool set 105 including the bonding tool, among other examples) may perform a series of operations 605 to join (e.g., bond) a carrier 610 (e.g., a first temporary carrier) to the interposer 220. As shown in FIG. 6A, a bottom surface of the interposer 220 is joined with a top surface of the carrier 610.

As shown in FIG. 6B, another semiconductor processing tool set (e.g., the die-attach tool set 130 including the pick-and-place tool and the reflow tool, among other examples) may perform a series of operations 615 to attach an IC device (e.g., a first IC device corresponding the SoC IC die 210, among other examples) to a top surface of the interposer 220 using the connection structures 230.

As shown in FIG. 6C, a semiconductor processing tool set (e.g., the encapsulation tool set 135, among other examples) may perform a series of operations 620 to encapsulate the IC device in a mold compound 235. In some implementations, a dispense tool of the encapsulation tool set 135 may dispense an underfill material (e.g., the underfill material 335) around the connection structures 230 prior to encapsulation of the IC device.

As shown in FIG. 6D, a semiconductor processing tool set (e.g., the RDL tool set 105 including the bonding tool and debonding tool, among other examples) may perform a series of operations 625 to join (e.g., bond) a top surface of the IC die (e.g., a top surface of the SoC IC die 210, among other examples) to a carrier 630 (e.g., a second temporary carrier). Additionally, and as shown in FIG. 6D, the series of operations 625 may include separating (e.g., debonding) the bottom surface of the interposer 220 from the top surface of the carrier 610.

As shown in FIG. 6E, a semiconductor processing tool set (e.g., the RDL tool set 105 including the photolithography tools and the one or more etch tools, among other examples) may perform a series of operations 635 to form the cavity 315. The series of operations 635 may include dispensing, patterning, and developing a photoresist material 640. The series of operations 635 may further include removing material (e.g. etching the interposer 220) to form the cavity 315.

As shown in FIG. 6F, a semiconductor processing tool set (e.g., the interconnect tool set 115 including the plating tool, among other examples) may perform a series of operations 645 to form portions of connection structures (e.g., portions of the connection structures 325) that connect to the electrically-conductive traces 225. Forming the portions of the connection structures may include forming UBM structures 650 and solder plating structures 655.

As shown in FIG. 6G, a semiconductor processing tool set (e.g., the die-attach tool set 130 including the pick-and-place tool and the reflow tool, among other examples) may perform a series of operations 660 to attach the IC device 320 to the bottom surface of the cavity 315. In some implementations, the IC device 320 may include bumps, solderballs, or plated pillar structures that complete the connection structures 325. Additionally, or alternatively, and as shown in FIG. 6G, another semiconductor processing tool set (e.g., the encapsulation tool set 135 including the dispense tool, among other examples) may dispense the underfill material 335 around the connection structures 325 and between the IC device 320 and the bottom surface of the cavity 315.

As shown in FIG. 6H, one or more semiconductor tool sets (e.g., the RDL tool set 105 including the debonding tool and the die-attach tool set 130 including the pick-and-place tool and the reflow tool, among other examples) have performed a series of operations 665. The series of operations 665 may include separating the temporary carrier 630 from the top surface of the IC die (e.g., the SoC IC die 210). Additionally, the series of operations 665 may include attaching the interposer 220 to the substrate 240 using the connection structures 250. The connection structures 250 may correspond to C4 connection structures.

As shown in FIG. 6H, the cavity 315 may provide a clearance (e.g., the clearance D2 of FIG. 3B) between the IC device 320 and the substrate 240 to reduce a likelihood of the IC device 320 interfering with the substrate 240 during a bending and/or a deformation of a semiconductor package (e.g., the semiconductor package 205) that includes the cavity 315. By reducing the likelihood of such an interference, damage to the IC device 320 (e.g., chipping and/or cracking, among other examples) and/or the substrate 240 (e.g., gouging of the top surface of the substrate 240) may be avoided to improve a yield, a quality, and/or a reliability of the semiconductor package including the cavity 315.

The operations provided by FIGS. 6A-6H are provided as examples. In practice, there may be additional operations, different operations, or differently arranged operations than those shown in FIGS. 6A-6H.

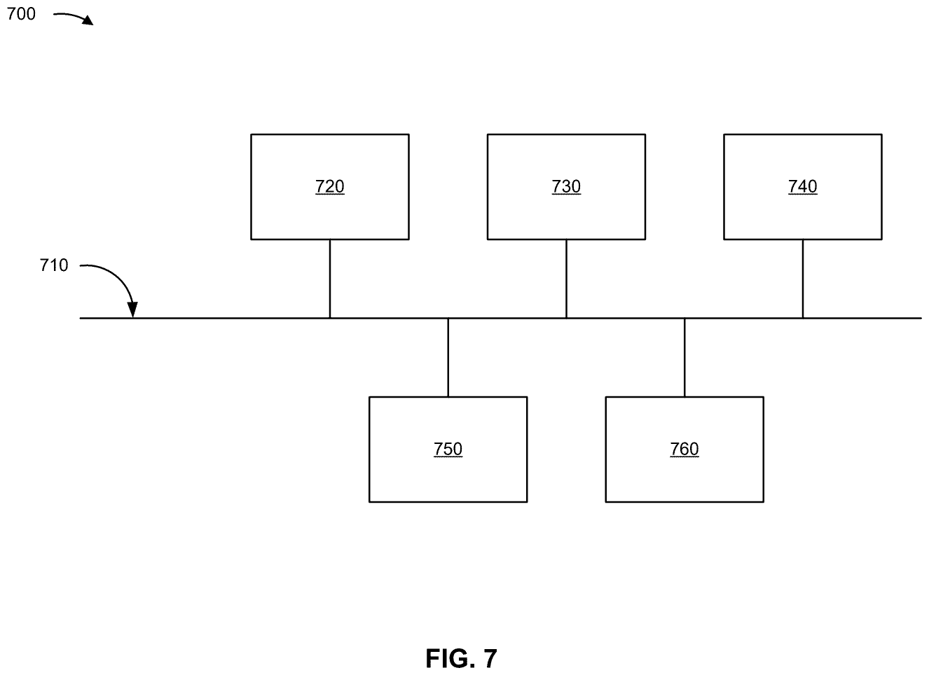

FIG. 7 is a diagram of example components of a device 700, which may correspond to one or more of the semiconductor processing tool sets 105-150. In some implementations, the semiconductor processing tool sets 105-150 include one or more devices 700 and/or one or more components of device 700. As shown in FIG. 7, device 700 may include a bus 710, a processor 720, a memory 730, an input component 740, an output component 750, and a communication component 760.

Bus 710 includes one or more components that enable wired and/or wireless communication among the components of device 700. Bus 710 may couple together two or more components of FIG. 7, such as via operative coupling, communicative coupling, electronic coupling, and/or electric coupling. Processor 720 includes a central processing unit, a graphics processing unit, a microprocessor, a controller, a microcontroller, a digital signal processor, a field-programmable gate array, an application-specific integrated circuit, and/or another type of processing component. Processor 720 is implemented in hardware, firmware, or a combination of hardware and software. In some implementations, processor 720 includes one or more processors capable of being programmed to perform one or more operations or processes described elsewhere herein.

Memory 730 includes volatile and/or nonvolatile memory. For example, memory 730 may include random access memory (RAM), read only memory (ROM), a hard disk drive, and/or another type of memory (e.g., a flash memory, a magnetic memory, and/or an optical memory). Memory 730 may include internal memory (e.g., RAM, ROM, or a hard disk drive) and/or removable memory (e.g., removable via a universal serial bus connection). Memory 730 may be a non-transitory computer-readable medium. Memory 730 stores information, instructions, and/or software (e.g., one or more software applications) related to the operation of device 700. In some implementations, memory 730 includes one or more memories that are coupled to one or more processors (e.g., processor 720), such as via bus 710.

Input component 740 enables device 700 to receive input, such as user input and/or sensed input. For example, input component 740 may include a touch screen, a keyboard, a keypad, a mouse, a button, a microphone, a switch, a sensor, a global positioning system sensor, an accelerometer, a gyroscope, and/or an actuator. Output component 750 enables device 700 to provide output, such as via a display, a speaker, and/or a light-emitting diode. Communication component 760 enables device 700 to communicate with other devices via a wired connection and/or a wireless connection. For example, communication component 760 may include a receiver, a transmitter, a transceiver, a modem, a network interface card, and/or an antenna.

Device 700 may perform one or more operations or processes described herein. For example, a non-transitory computer-readable medium (e.g., memory 730) may store a set of instructions (e.g., one or more instructions or code) for execution by processor 720. Processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry is used instead of or in combination with the instructions to perform one or more operations or processes described herein. Additionally, or alternatively, processor 720 may be configured to perform one or more operations or processes described herein. Thus, implementations described herein are not limited to any specific combination of hardware circuitry and software.

The number and arrangement of components shown in FIG. 7 are provided as an example. Device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

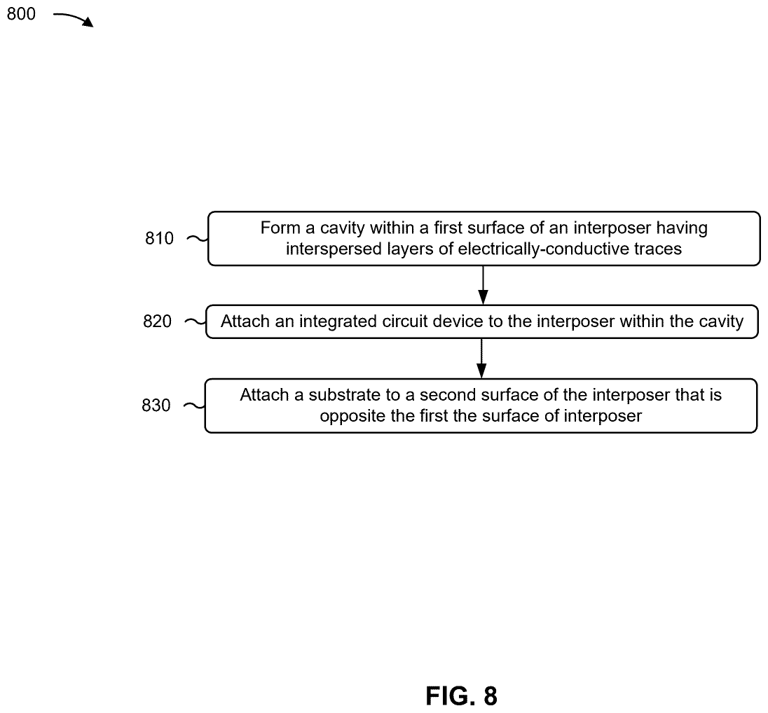

FIG. 8 is a flowchart of an example process 800 associated with forming a semiconductor package described herein. In some implementations, one or more process blocks of FIG. 8 are performed by one or more of the semiconductor processing tool sets 105-150. Additionally, or alternatively, one or more process blocks of FIG. 8 may be performed by one or more components of device 700, such as processor 720, memory 730, input component 740, output component 750, and/or communication component 760.

As shown in FIG. 8, process 800 may include forming a cavity within a first surface of an interposer having layers of electrically-conductive traces (block 810). For example, one or more of the semiconductor processing tool sets 105-150, such as the photolithography tools and one or more of the etch tools of the RDL tool set 105, among other examples, may form a cavity 315 within a surface of an interposer 220 having interspersed layers of electrically conductive traces (e.g., the electrically-conductive traces 225), as described above.

As further shown in FIG. 8, process 800 may include attaching an IC device to the interposer within the cavity (block 820). For example, one or more of the semiconductor processing tool sets 105-150, such as the pick-and-place tool and the reflow tool of the die-attach tool set 130, among other examples, may attach an IC device 320 to the interposer within the cavity 315, as described above.

As further shown in FIG. 8, process 800 may include attaching a substrate to the surface of the interposer (block 830). For example, one or more of the semiconductor processing tool sets 105-150, such as the pick-and-place tool and the reflow tool of the SMT tool set 145, among other examples, may attach a substrate 240 to the surface of the interposer 220, as described above.

Process 800 may include additional implementations, such as any single implementation or any combination of implementations described below and/or in connection with one or more other processes described elsewhere herein.

In a first implementation, attaching the IC device 320 to the interposer 220 within the cavity 315 includes attaching the IC device 320 to the interposer 220 within the cavity using connection structures 325 between the IC device 320 and a layer of electrically-conductive traces, of the interspersed layers of electrically-conductive traces, that are exposed at a bottom surface of the cavity 315.

In a second implementation, alone or in combination with the first implementation, attaching the IC device 320 to the interposer 220 within the cavity 315 includes attaching the IC device 320 to the interposer 220 within the cavity 315 using connection structures 325 between the IC device 320 and land structures 405 extending through a bottom surface of the cavity 315 to a layer of electrically-conductive traces, of the interspersed layers of electrically-conductive traces, embedded below the bottom surface.

In a third implementation, alone or in combination with one or more of the first and second implementations, the IC device 320 corresponds to a first IC device 320a and the method further including attaching a second IC device 320b to the interposer 220 within the cavity 315 and adjacent to the first IC device 320a.

In a fourth implementation, alone or in combination with one or more of the first through third implementations, forming the cavity 315 within the surface of the interposer 220 includes forming the cavity 315 using a patterning and etching process.

In a fifth implementation, alone or in combination with one or more of the first through fourth implementations, forming the cavity 315 within the surface of the interposer 220 includes forming the cavity 315 using a laser ablation process.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

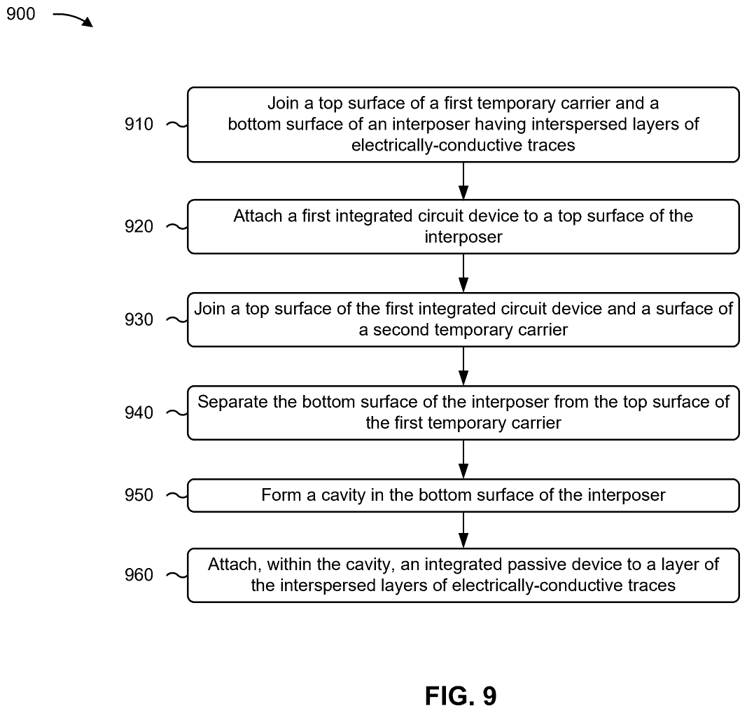

FIG. 9 is a flowchart of an example process 900 associated with forming a semiconductor package described herein. In some implementations, one or more process blocks of FIG. 9 are performed by one or more of the semiconductor processing tool sets 105-150. Additionally, or alternatively, one or more process blocks of FIG. 9 may be performed by one or more components of device 700, such as processor 720, memory 730, input component 740, output component 750, and/or communication component 760.

As shown in FIG. 9, process 900 may include joining a top surface of a first temporary carrier and a bottom surface of an interposer having interspersed layers of electrically-conductive traces (block 910). For example, one or more of the semiconductor processing tool sets 105-150, such as the bonding tool of the RDL tool set 105, among other examples, may join a top surface of a first temporary carrier 610 and a bottom surface of an interposer 220 having interspersed layers of electrically-conductive traces (e.g., the electrically-conductive traces 225), as described above.

As further shown in FIG. 9, process 900 may include attaching a first IC device to a top surface of the interposer (block 920). For example, one or more of the semiconductor processing tool sets 105-150, such as the pick-and-place tool and the reflow tool of the die-attach tool set 130, among other examples, may attach a first IC device 210 to a top surface of the interposer 220, as described above.

As further shown in FIG. 9, process 900 may include joining a top surface of the first integrated circuit device and a second temporary carrier (block 930). For example, one or more of the semiconductor processing tool sets 105-150, such as the bonding tool of the RDL tool set 105, among other examples, may join a top surface of the first IC device 210 and a second temporary carrier 630, as described above.

As further shown in FIG. 9, process 900 may include separating the bottom surface of the interposer from the top surface of the first temporary carrier (block 940). For example, one or more of the semiconductor processing tool sets 105-150, such as the debonding tool of the RDL tool set 105, among other examples, may separate the bottom surface of the interposer 220 from the top surface of the first temporary carrier 610, as described above.

As further shown in FIG. 9, process 900 may include forming a cavity in the bottom surface of the interposer (block 950). For example, one or more of the semiconductor processing tool sets 105-150, such as the photolithography tools and the one or more etch tools of the RDL tool set 105, among other examples, may form a cavity 315 in the bottom surface of the interposer 220, as described above.

As further shown in FIG. 9, process 900 may include attaching, within the cavity, an integrated passive device to a layer of the interspersed layers of electrically-conductive traces (block 960). For example, one or more of the semiconductor processing tool sets 105-150, such as the pick-and-place tool and the reflow tool of the die-attach tool set 130, among other examples, may attach an IPD (e.g., the IC device 320) to a layer of the layers of interspersed electrically-conductive traces, as described above.

Process 900 may include additional implementations, such as any single implementation or any combination of implementations described below and/or in connection with one or more other processes described elsewhere herein.

In a first implementation, joining the bottom surface of the interposer 220 and the top surface of the first temporary carrier 610 includes forming the interposer 220 on the top surface of the first temporary carrier 610 using a redistribution layer formation process.

In a second implementation, alone or in combination with the first implementation, joining the bottom surface of the interposer 220 to the top surface of the first temporary carrier 610 includes bonding a printed circuit board to the top surface of the first temporary carrier 610.

In a third implementation, alone or in combination with one or more of the first and second implementations, the cavity 315 corresponds to a first cavity 315c and the IPD corresponds to a first IPD (e.g., the IC device 320c), and the method further including forming a second cavity 315d in the bottom surface of the interposer 220, and attaching a second IPD (e.g., the IC device 320d) to the interposer 220 within the second cavity 315d.

In a fourth implementation, alone or in combination with one or more of the first through third implementations, attaching the IPD to the interposer 220 within the cavity 315 includes attaching the IPD using a set of connection structures 325 that include underbump metal structures 650 and/or plating structures 655.

In a fifth implementation, alone or in combination with one or more of the first through fourth implementations, process 900 includes dispensing an underfill material 335 around the set of connection structures 325.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Some implementations herein describe a semiconductor package. The semiconductor package, which may correspond to a high-performance computing (HPC) package, includes an interposer, a substrate, and an IC device between the interposer and the substrate. The IC device, which may correspond to an IPD, is attached to the interposer within a cavity of the interposer. Attaching the IC device within the cavity of the interposer creates a clearance between the IC device and the substrate.

In this way, a likelihood of the IC device contacting the substrate during a bending and/or a deformation of the semiconductor package is reduced. By reducing the likelihood of such contact, damage to the IC device and/or the substrate may be avoided to increase a reliability and/or yield of the semiconductor package.

As described in greater detail above, some implementations described herein provide a semiconductor package. The semiconductor package includes an interposer having interspersed layers of electrically-conductive traces and a bottom surface having a cavity, where the cavity has a recessed surface. The semiconductor package includes a substrate below the interposer including a top surface, where the top surface is electrically and/or mechanically connected to the bottom surface of the interposer using a first set of connection structures. The semiconductor package includes an integrated circuit device between the interposer and the substrate and including a top surface, where the top surface of the integrated circuit device is electrically and/or mechanically connected to the interposer within the cavity using a second set of connection structures, and where the integrated circuit device is electrically connected to the interspersed layers of electrically-conductive using the second set of connection structures.

As described in greater detail above, some implementations described herein provide a method. The method includes forming a cavity within a first surface of an interposer having interspersed layers of electrically-conductive traces. The method includes attaching an integrated circuit device to the interposer within the cavity. The method includes attaching a substrate to a second surface of the interposer that is opposite the first surface.

As described in greater detail above, some implementations described herein provide a method. The method includes joining a top surface of a first temporary carrier and a bottom surface of an interposer having interspersed layers of electrically-conductive traces. The method includes attaching a first integrated circuit device to a top surface of the interposer. The method includes joining a top surface of the first integrated circuit device and a surface of a second temporary carrier. The method includes separating the bottom surface of the interposer from the top surface of the first temporary carrier. The method includes forming a cavity in the bottom surface of the interposer. The method includes attaching, within the cavity, an integrated passive device to a layer of the interspersed layers of electrically-conductive traces.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer comprising:
a plurality of interspersed layers of electrically-conductive traces, and a bottom surface having a cavity,
wherein the cavity has a recessed surface;
a substrate, below the interposer, comprising a top surface,
wherein the top surface is electrically and/or mechanically connected to the bottom surface of the interposer using a first set of connection structures; and
an integrated circuit device between the interposer and the substrate and comprising a top surface,
wherein the top surface of the integrated circuit device is electrically and/or mechanically connected to the recessed surface using a second set of connection structures, and
wherein the integrated circuit device is electrically connected to the plurality of interspersed layers of electrically-conductive traces using the second set of connection structures.

2. The semiconductor package of claim 1, wherein a clearance between a bottom surface of the integrated circuit device and the top surface of the substrate is in a range of approximately 10 microns to approximately 60 microns.

3. The semiconductor package of claim 1, wherein a depth of the cavity is greater than approximately 15 microns.

4. The semiconductor package of claim 1, wherein the cavity comprises at least one approximately vertical wall.

5. The semiconductor package of claim 4, wherein a clearance between the integrated circuit device and the approximately vertical wall is in a range of approximately 100 microns to approximately 300 microns.

6. The semiconductor package of claim 1, wherein the integrated circuit device corresponds to an integrated passive device.

7. The semiconductor package of claim 6, wherein the integrated passive device corresponds to a capacitor.

8. The semiconductor package of claim 1, wherein the integrated circuit device corresponds to an integrated circuit die.

9. A semiconductor package, comprising:
an interposer comprising:
a plurality of electrically-conductive traces, and
a bottom surface including at least one cavity having a recessed surface and at least one approximately vertical wall;
a substrate, disposed below the interposer and having a top surface, wherein the top surface is coupled to the bottom surface of the interposer using a first set of connection structures; and
at least one integrated circuit device disposed within the at least one cavity and between the interposer and the substrate,
wherein the at least one integrated circuit device is attached to the recessed surface via a second set of connection structures, and
wherein the at least one cavity is configured to provide a clearance between a bottom surface of the at least one integrated circuit device and the top surface of the substrate.

10. The semiconductor package of claim 9, wherein the recessed surface comprises land structures extending through the cavity to the plurality of electrically-conductive traces.

11. The semiconductor package of claim 9, wherein the second set of connection structures comprises one or more underbump metallization structures or one or more solder plating structures.

12. The semiconductor package of claim 9, further comprising:
an underfill material, disposed between the recessed surface and the integrated circuit device, surrounding the second set of connection structures.

13. The semiconductor package of claim 9, wherein the cavity contains a plurality of integrated circuit devices disposed adjacent to each other.

14. The semiconductor package of claim 13, wherein the plurality of integrated circuit devices are electrically connected in parallel or in series through the plurality of electrically-conductive traces of the interposer.

15. A semiconductor package, comprising:
an interposer comprising:
an electrically-conductive trace, and
a bottom surface including a cavity having a recessed surface and at least one land structure extending to the electrically-conductive trace;
a substrate, disposed below the interposer, comprising a top surface electrically and mechanically coupled to the bottom surface of the interposer using a first set of solder bump connection structures;
a pair of integrated circuit devices, disposed side by side within the cavity and between the interposer and the substrate, that are electrically and mechanically connected to the recessed surface through the at least one land structure using a second set of solder bump connection structures; and
an underfill material, surrounding the second set of solder bump connection structures, filling a space between the pair of integrated circuit devices and the recessed surface.

16. The semiconductor package of claim 15, wherein the pair of integrated circuit devices are electrically coupled in parallel through the electrically-conductive trace.

17. The semiconductor package of claim 15, wherein the interposer comprises a silicon interposer including redistribution layers.

18. The semiconductor package of claim 15, wherein the underfill material comprises an epoxy polymer material.

19. The semiconductor package of claim 15, wherein the first set of solder bump connection structures corresponds to controlled collapse chip connection (C4) structures.

20. The semiconductor package of claim 15, wherein the cavity has a depth greater than 15 microns and the underfill material fills the cavity below a top surface of the pair of integrated circuit devices.
